(19) United States
(12) Patent Application Publication
(10) Pub. No.: US 2022/0310958 A1
(43) Pub. Date: Sep. 29, 2022

(54) LIGHT-EMITTING DEVICE AND DISPLAY PANEL

(71) Applicant: Yungu (Gu'an) Technology Co., Ltd., Langfang (CN)

(72) Inventors: Mengyu LIU, Langfang (CN); Yu GAO, Langfang (CN)

(73) Assignee: Yungu (Gu'an) Technology Co., Ltd., Langfang (CN)

(21) Appl. No.: 17/832,953

(22) Filed: Jun. 6, 2022

Related U.S. Application Data
(63) Continuation of application No. PCT/CN2021/088794, filed on Apr. 21, 2021.

(30) Foreign Application Priority Data
Jun. 11, 2020 (CN) 202010531638.3

(51) Int. Cl. H01L 51/50

(52) U.S. Cl. CPC H01L 51/5004; H01L 51/5012; H01L 2251/552

(57) ABSTRACT

A light-emitting device and a display panel. The light-emitting device includes an electron transport layer, an energy level matching layer, and a light-emitting layer that are stacked. A first difference exists between an average activation energy of the electron transport layer and an average activation energy of the energy level matching layer; a second difference exists between the average activation energy of the energy level matching layer and an average activation energy of a host material of the light-emitting layer; an absolute value of the first difference is less than an absolute value of the second difference.

### CROSS REFERENCE

The present application is a continuation-application of International (PCT) Patent Application No. PCT/CN2021/088794, filed on Apr. 21, 2021, which claims foreign priority of Chinese Patent Application No. 202010531638.3, filed on Jun. 11, 2020, in the China National Intellectual Property Administration, the entire contents of which are hereby incorporated by reference in their entireties.

### FIELD

The present disclosure relates to the field of display technologies, and in particular to a light-emitting device and a display panel.

### BACKGROUND

When a display panel is used as a display device of a mobile phone, etc., its actual use temperature generally fluctuates in the range of 25° C.-55° C. When the display panel is in low grayscale, the white light color will shift with temperature. The reason for this phenomenon may be that the light-emitting efficiency of some light-emitting devices changes significantly with temperature when the grayscale is low; for example, the higher the temperature, the lower the light-emitting efficiency of the blue light-emitting device.

At present, one-time programmable (OTP) is generally applied to calibrate the color matching ratio of blue light-emitting devices, red light-emitting devices and green light-emitting devices at 25° C., but this method cannot solve the problem of white light color shifts when the temperature exceeds 25° C.

### SUMMARY

A technical solution adopted by an embodiment of the present disclosure is to provide a light-emitting device, comprising: an electron transport layer, an energy level matching layer, and a light-emitting layer that are stacked; wherein a first difference exists between an average activation energy of the electron transport layer and an average activation energy of the energy level matching layer; a second difference exists between the average activation energy of the energy level matching layer and an average activation energy of a host material of the light-emitting layer; an absolute value of the first difference is less than an absolute value of the second difference.

Another technical solution adopted by an embodiment of the present disclosure is to provide a display panel, comprising the light-emitting device as described above.

The beneficial effect of an embodiment of the present disclosure is that the light-emitting device provided has a first difference between the average activation energy of the electron transport layer and the average activation energy of the energy level matching layer, and a second difference between the average activation energy of the energy level matching layer and the average activation energy of the host material of the light-emitting layer. The absolute value of the first difference is less than the absolute value of the second difference. In the calculation of activation energy, activation energy is related to temperature. In the embodiment of the present disclosure, the average activation energy is used to measure the energy level matching in the light-emitting device, so that the temperature, the injection efficiency of electrons, the migration efficiency of electrons and other factors can be considered comprehensively, and it improves the light-emitting efficiency of the light-emitting device while reducing the phenomenon that the light-emitting efficiency changes substantially with temperature.

### BRIEF DESCRIPTION OF THE DRAWINGS

To illustrate the technical solutions more clearly in the embodiments of the present disclosure, the following will be briefly described in the description of the embodiments required to use the attached drawings. It is obvious that the following description of the attached drawings are only some of the embodiments of the present disclosure, and those skilled in the art, without creative work, can also obtain other attached drawings based on these drawings.

FIG. 1 is a structural schematic view of a light-emitting device according to an embodiment of the present disclosure.

FIG. 2 is a perspective view of a cyclic voltammetry curve of an energy level matching layer in Comparative Example 1.

FIG. 3 is a perspective view of a cyclic voltammetry curve of an energy level matching layer in Experimental Example 1.

FIG. 4 is a schematic view of a light-emitting efficiency curve of a light-emitting device corresponding to Comparative Example 1 as a function of temperature.

FIG. 5 is a schematic view of a light-emitting efficiency curve of a light-emitting device corresponding to Experimental Example 1 as a function of temperature.

FIG. 6 is a schematic view of color coordinates of Comparative Example 1 and Experimental Example 1 as a function of temperature.

FIG. 7 is a structural schematic view of a light-emitting device according to another embodiment of the present disclosure; wherein an energy level adjustment layer and a hole transport layer are stacked on a side of a light-emitting layer away from an energy level matching layer shown in FIG. 1.

FIG. 8 is a schematic view of color coordinates of Comparative Example 2 and Experimental Example 2 as a function of time.

FIG. 9 is a structural schematic view of a display panel according to an embodiment of the present disclosure.

### DETAILED DESCRIPTION

The technical solutions in the embodiments of the present disclosure will be clearly and completely described below in conjunction with the accompanying drawings in the embodiments of the present disclosure. Obviously, the described embodiments are only a part of the embodiments of the present disclosure, and not all of them. Based on the embodiments in the present disclosure, all other embodiments obtained by those skilled in the art without making creative labor fall within the scope of the present disclosure.

Referring to FIG. 1. FIG. 1 is a structural schematic view of a light-emitting device according to an embodiment of the present disclosure. The light-emitting device 10 includes an electron transport layer 100, an energy level matching layer 102, and a light-emitting layer 104 that are stacked. A first difference ΔEa1 exists between an average activation energy of the electron transport layer 100 and an average activation energy of energy level matching layer 102. A second difference ΔEa2 exists between an average activation energy of the energy level matching layer 102 and an average activation energy of a host material of the light-emitting layer 104. The absolute value of the first difference ΔEa1 is less than the absolute value of the second difference ΔEa2.

The activation energy refers to an energy required for a substance to become activated molecules. The lower the activation energy, the lower the barrier to overcome. The activation energy may be calculated with the following Arrhenius formula: Ea=E₀+mRT, where Ea is the activation energy, E₀ and m are constants independent of temperature, T is temperature, and R is molar gas constant. That is, it can be seen from the above formula that the activation energy is related to temperature. In addition, the unit of activation energy obtained by the above calculation formula is Joule J, and the unit of activation energy can be converted into electron volt eV through a simple conversion formula, where the conversion formula is: 1 eV=1.602176565×10⁻¹⁹ J.

When the electron transport layer 100, the energy level matching layer 102 and the host material of the light-emitting layer 104 are each formed of a single substance, the activation energy Ea of each corresponding single substance is the average activation energy of the electron transport layer 100 or the energy level matching layer 102 or the host material of the light-emitting layer 104.

When the electron transport layer 100, the energy level matching layer 102, and the host material of the light-emitting layer 104 are each formed by mixing multiple substances, the calculation process of the average activation energy of the electron transport layer 100 or the energy level matching layer 102 or the host material of the light-emitting layer 104 formed of multiple substances may be as follows: obtaining a product value of the activation energy of each substance and its corresponding molar mass fraction; summing the product values to obtain the average activation energy. Alternatively, in other embodiments, thermogravimetric analysis may be directly performed on the entire electron transport layer 100 or the energy level matching layer 102 or the host material of the light-emitting layer 104, and the corresponding average activation energy may be directly calculated according to results of the thermogravimetric analysis. The thermogravimetric analysis refers to a method of obtaining the relationship between the mass of a substance and the temperature (or time) at programmed temperatures. When a thermogravimetric curve is obtained by the thermogravimetric analysis, the average activation energy can be calculated by a difference-subtraction differential (Freeman-Carroll) method or an integral (OWAZa) method.

In the related art, the highest occupied molecular orbital (HOMO)/lowest occupied molecular orbital (LOMO) is generally used to measure the energy level matching of the light-emitting device 10. HOMO/LOMO only considers the injection efficiency of electrons. However, in the embodiments of the present disclosure, the average activation energy is used to measure the energy level matching of the light-emitting device 10, so that the temperature, electron injection efficiency and migration efficiency can be comprehensively considered. Compared to the related HOMO/LOMO methods, the lifetime of the light-emitting device 10 may be prolonged, the light-emitting efficiency of the light-emitting device 10 may be improved, and the phenomenon that the light-emitting efficiency changes drastically with temperature may be mitigated.

In the embodiment, the energy level matching layer 102 may be a hole blocking layer, and the material of the energy level matching layer 102 may be at least one of: 2,9-dimethyl-4,7-diphenyl-1,10-phenanthroline BCP, 1,3,5-Tris(N-phenyl-2-benzimidazole)benzene TPBi, Tris(8-hydroxyquinoline)aluminum(III) Alq3, 8-hydroxyquinoline-lithium Liq, Bis(2-methyl-8-hydroxyquinoline)(4-phenylphenol)aluminum(III) BAlq, 3-(biphenyl-4-yl)-5-(4-tert-butylphenyl)-4-phenyl-4H-1,2,4-triazole TAZ, etc. The above-mentioned design of the energy level matching layer 102 may achieve the purpose of energy level matching and block the holes from the anode, so as to further improve the light-emitting efficiency of the light-emitting device 10.

Further, when selecting the material of the energy level matching layer 102, a material with a current change rate of less than 1% that has undergone the cyclic voltammetry test may be selected. The temperature of the cyclic voltammetry test may be room temperature or higher. This design method may ensure the performance stability of the energy level matching layer 102 during long-term operation and under corresponding temperature, thereby improving the problem of the light-emitting efficiency varying with temperature at low gray levels.

In some embodiments, the light-emitting layer 104 is a blue light-emitting layer. The absolute value of the first difference ΔEa1 between the average activation energy of the electron transport layer 100 and the average activation energy of the energy level matching layer 102 is less than 0.05 eV, and the absolute value of the second difference ΔEa2 between the average activation energy of the energy level matching layer 102 and the average activation energy of the light-emitting layer 104 is greater than or equal to 0.1 eV and less than or equal to 0.15 eV. The absolute value of the first difference ΔEa1 may be 0.02 eV, 0.04 eV, etc., and the absolute value of the second difference ΔEa2 may be 0.12 eV, 0.14 eV, etc. The design of the ranges of the first difference ΔEa1 and the second difference ΔEa2 may effectively improve the light-emitting efficiency of the blue light-emitting layer at different temperatures and reduce the difference in light-emitting efficiency at different temperatures, thereby reducing the white light shift.

In an application scenario, the average activation energy of the energy level matching layer 102 has a difference of −0.05 eV to 0 eV (for example, −0.02 eV, −0.03 eV, etc.) compared to the average activation energy of the electron transport layer 100. The average activation energy of the blue light-emitting layer has a difference of 0.05 eV to 0.15 eV (for example, 0.11 eV, 0.14 eV, etc.) compared to the average activation energy of the electron transport layer 100. The design method may make the blue light-emitting device have a higher lifespan and light-emitting efficiency.

In an application scenario, the blue light-emitting layer includes a blue light-emitting host material BH and a blue light-emitting doped material BD, and a third difference ΔEa3 exists between the average activation energy of the blue light-emitting doped material BD and the average activation energy of the energy level matching layer 102. The absolute value of the third difference ΔEa3 is less than the absolute value of the second difference ΔEa2. The main role of the blue light-emitting host material BH is to transfer energy and prevent triplet energy from being overwhelmed, and the main role of the blue light-emitting doped material BD is to emit light. When the blue light-emitting layer emits light, energy is transferred between the blue light-emitting host material BH and the blue light-emitting doped material BD. The design of the above-mentioned average activation energy may make the electrons transmitted by the energy level matching layer 102 reach the blue light-emitting dopant material BD more easily, and the blue light-emitting host material BH may effectively transfer energy to the blue light-emitting dopant material BD, reducing the probability of energy reflow and ensuring light-emitting efficiency.

In the embodiments, the blue light-emitting host material BH may be a carbazole group derivative, an aryl silicon derivative, an aromatic derivative, a metal complex derivative, etc., and the blue light-emitting dopant material BD may be fluorescent doped materials (for example, porphyrin-based compounds, coumarin-based dyes, quinacridone-based compounds, arylamine-based compounds, etc.) or phosphorescent doped materials (for example, complexes containing metal iridium, etc.), and the like.

Further, the absolute value of the third difference ΔEa3 between the average activation energy of the blue light-emitting dopant material BD and the average activation energy of the energy level matching layer 102 is less than 0.05 eV, for example, the absolute value of the third difference ΔEa3 may be 0.04 eV, 0.02 eV, etc. The absolute value of the second difference ΔEa2 between the blue light-emitting host material BH and the average activation energy of the energy level matching layer 102 is greater than or equal to 0.1 eV and less than or equal to 0.15 eV, and the absolute value of the second difference ΔEa2 may be 0.12 eV, 0.14 eV, etc. In addition, the difference between the average activation energy of the blue light-emitting dopant material BD and the average activation energy of the blue light-emitting host material BH may be between 0.05 eV and 0.1 eV, for example, 0.06 eV, 0.08 eV, etc. The design of the third difference ΔEa3 and the second difference ΔEa2 may effectively improve the light-emitting efficiency of the blue light-emitting layer. For example, the design of the third difference ΔEa3 is beneficial to accumulate a certain number of holes and electrons, which then combine to form excitons to enhance light-emitting efficiency. The design of the second difference ΔEa2 is conducive to the blue light-emitting host material BH that can effectively transfer energy to the blue light-emitting doped material BD, reducing the probability of energy reflow and ensuring light-emitting efficiency.

To verify the actual effect of the above designs, the following Comparative Example 1 and Experimental Example 1 are designed.

The activation energy design of each layer in Comparative Example 1 is as follows: the absolute value of the difference between the average activation energy of the blue light-emitting host material BH and the average activation energy of the blue light-emitting doped material BD is 0.02 eV, and the absolute value of the difference between the average activation energy of the blue light-emitting doped material BD and the average activation energy of the energy level matching layer 102 is 0.02 eV. The absolute value of the difference between the average activation energy of the blue light-emitting host material BH and the average activation energy of the energy level matching layer 102 is 0.03 eV, and the absolute value of the difference between the average activation energy of the energy level matching layer 102 and the average activation energy of the electron transport layer 100 is 0.03 eV. Specifically, in Comparative Example 1, the difference between the activation energy of the electron transport layer 100 and the activation energy of any one of the blue light-emitting host material BH, the blue light-emitting doped material BD, and the energy level matching layer 102 is positive.

The activation energy design of each layer in Experimental Example 1 is as follows: the absolute value of the difference between the average activation energy of the blue light-emitting host material BH and the average activation energy of the blue light-emitting doped material BD is 0.1 eV, and the absolute value of the difference between the average activation energy of the blue light-emitting doped material BD and the average activation energy of the energy level matching layers 102 is 0.04 eV. The absolute value of the difference between the average activation energy of the blue light-emitting host material BH and the average activation energy of the energy level matching layer 102 is 0.11 eV, and the absolute value of the difference between the average activation energy of the energy level matching layer 102 and the average activation energy of the electron transport layer 100 is 0.02 eV. Specifically, in Experimental Example 1, the difference between the activation energy of the electron transport layer 100 and the activation energy of any one of the blue light-emitting host material BH and the blue light-emitting doped material BD is positive; and the difference between the activation energy of the energy level matching layer 102 and the activation energy of the electron transport layer 100 is negative.

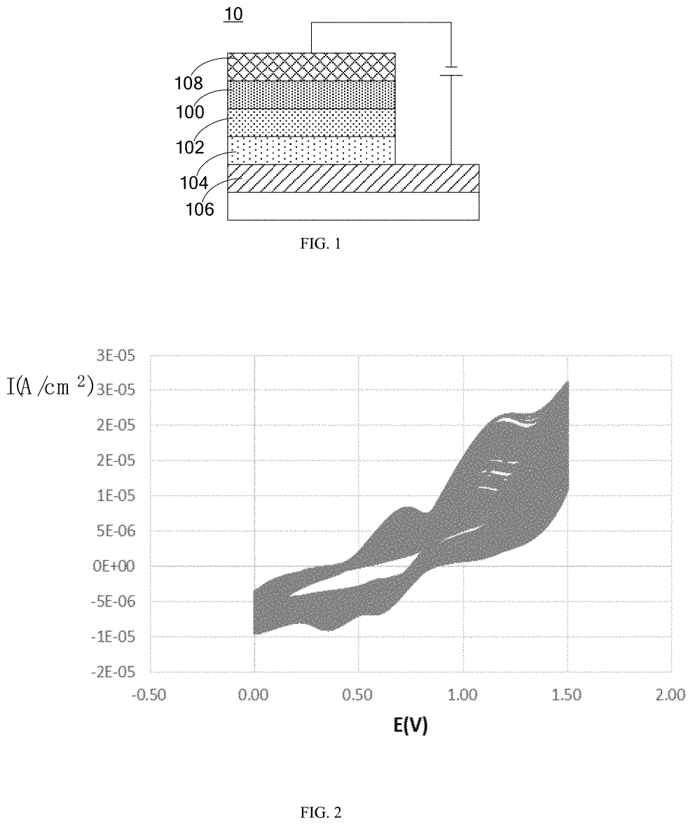

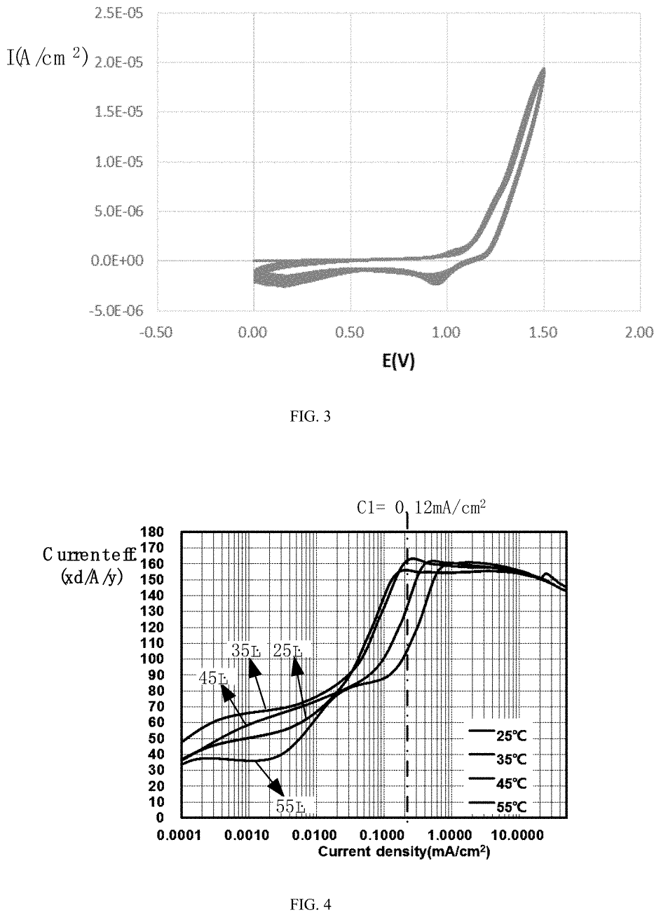

Referring to FIGS. 2 and 3, FIG. 2 is a perspective view of a cyclic voltammetry curve of an energy level matching layer in Comparative Example 1, and FIG. 3 is a perspective view of a cyclic voltammetry curve of an energy level matching layer in Experimental Example 1. It can be seen from the figures that the material of the energy level matching layer of Experimental Example 1 has a small current change after 100 cycles of cyclic voltammetry. After calculation, it is found that the current change rate of the material of the energy level matching layer of Comparative Example 1 after 100 cycles of cyclic voltammetry is 4.4%, while the current change rate of the material of the energy level matching layer of Experimental Example after 100 cycles of cyclic voltammetry is only 0.5%.

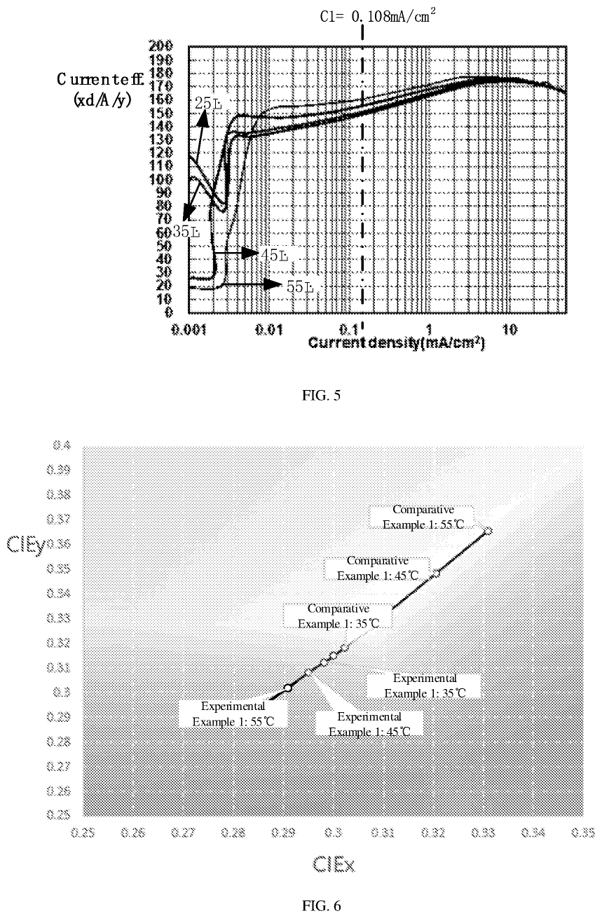

Referring to FIGS. 4 and 5, FIG. 4 is a schematic view of a light-emitting efficiency curve of a light-emitting device corresponding to Comparative Example 1 as a function of temperature, and FIG. 5 is a schematic view of a light-emitting efficiency curve of a light-emitting device corresponding to Experimental Example 1 as a function of temperature. It can be seen from the figures that the light-emitting efficiency change of the light-emitting device of Experimental Example 1 at various temperatures is significantly less than that of the light-emitting device of Comparative Example 1. The light-emitting efficiency of Comparative Example 1 is less than that of Experimental Example 1. To achieve the same display brightness, the driving current required by Comparative Example 1 is relatively large. For example, as shown in FIGS. 4 and 5, to achieve the same brightness, the current density of 0.12 mA/cm² is required in Comparative Example 1, and the current density of 0.108 mA/cm² is required in Experimental Example 1.

In addition, after comparison, it is found that, corresponding to the same current density of 0.12 mA/cm², the light-emitting efficiency of the light-emitting device in Comparative Example 1 at 55° C. is less than the light-emitting efficiency at 25° C., and is 88.5% of the light-emitting efficiency at 25° C. Corresponding to the same current density of 0.108 mA/cm², the light-emitting efficiency of the light-emitting device in Experimental Example 1 at 55° C. is greater than the light-emitting efficiency at 25° C., and is 111.6% of the light-emitting efficiency at 25° C.

Further, referring to FIG. 6, FIG. 6 is a schematic view of color coordinates of Comparative Example 1 and Experimental Example 1 as a function of temperature. It can be seen from the figure that, compared to Comparative Example 1, the white light of Experimental Example 1 has a smaller shift with temperature.

The foregoing embodiments mainly focus on the case where the light-emitting layer 104 is a blue light-emitting layer. Of course, the above methods are also applicable to light-emitting layers of other colors. For example, when the light-emitting layer 104 is a green light-emitting layer, the absolute value of the first difference between the average activation energy of the energy level matching layer 102 and the average activation energy of the electron transport layer 100 is less than 0.05 eV, and the absolute value of the second difference between the average activation energy of the green light-emitting host material GH and the average activation energy of the energy level matching layer 102 is less than 0.05 eV. The absolute value of the difference between the average activation energy of the green light-emitting host material GH and the average activation energy of the green light-emitting doped material GD is between 0.05 eV and 0.1 eV, and the absolute value of the third difference between the average activation energy of the green light-emitting doped material GD and the average activation energy of the energy level matching layer 102 is less than 0.1 eV. In an application scenario, the energy level matching layer 102 has a difference in average activation energy greater than 0 and less than 0.05 eV relative to the electron transport layer 100; the green light-emitting host material has a difference in average activation energy greater than −0.05 eV and less than 0 eV relative to the electron transport layer 100; the green light-emitting dopant material has a difference in activation energy greater than or equal to −0.1 eV and less than or equal to −0.05 eV relative to the green light emitting host material.

For another example, when the light-emitting layer 104 is a red light-emitting layer, the absolute value of the first difference between the average activation energy of the energy level matching layer 102 and the average activation energy of the electron transport layer 100 is less than 0.05 eV, and the absolute value of the second difference between the average activation energy of the red light-emitting host material RH of the red light-emitting layer and the average activation energy of the energy level matching layer 102 is less than 0.05 eV. The absolute value of the difference between the average activation energy of the red light-emitting host material RH and the average activation energy of the red light-emitting doped material RD is between 0.08 eV and 0.12 eV, and the absolute value of the third difference between the average activation energy of the red light-emitting doped material RD and the average activation energy of the energy level matching layer 102 is between 0.08 eV and 0.12 eV. In an application scenario, the energy level matching layer 102 has a difference in average activation energy greater than 0 and less than 0.05 eV relative to the electron transport layer 100; the red light-emitting host material has a difference in average activation energy greater than 0 to 0.05 eV relative to the electron transport layer 100; the red light-emitting dopant material has a difference in activation energy greater than or equal to −0.1 eV and less than or equal to 0 eV relative to the red light emitting host material.

In addition, when the energy level matching layer 102 is a hole blocking layer, the light-emitting device provided by some embodiments of the present disclosure may further include: a first energy level layer disposed between the hole blocking layer and the light-emitting layer 104, and the average activation energy of the first energy level layer is between the average activation energy of the hole blocking layer and the average activation energy of the light-emitting layer 104. This design method may reduce the lifetime loss caused by the impact at the interface between the hole blocking layer and the light-emitting layer 104 and improve the lifetime of the light-emitting device.

And/or, the light-emitting device may further include a second energy level layer disposed between the hole blocking layer and the electron transport layer 100, and the average activation energy of the second energy level layer is between the average activation energy of the hole blocking layer and the average activation energy of the electron transport layer 100. This design method may reduce the lifetime loss caused by the impact at the interface between the hole blocking layer and the electron transport layer 100 and improve the lifetime of the light-emitting device.

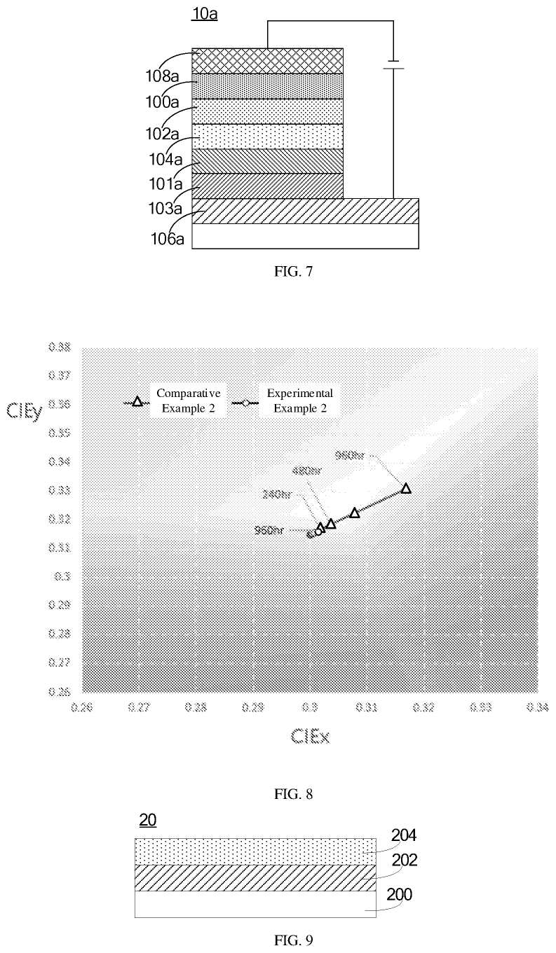

Referring to FIG. 1 again, the light-emitting device 10 shown in FIG. 1 has a single-layer device structure, which may further include a cathode 108 and an anode 106. Of course, in other embodiments, the light-emitting device 10 may also include other structures, for example, as shown in FIG. 7, which is a structural schematic view of a light-emitting device according to another embodiment of the present disclosure. A side of the light-emitting layer 104a (equivalent to 104 in FIG. 1) facing away from the energy level matching layer 102a (equivalent to 102 in FIG. 1) shown in FIG. 1, may be arranged with an energy level adjustment layer 101a and a hole transport layer 103a that are stacked. A fourth difference ΔEa4 exists between the average activation energy of the hole transport layer 103a and the average activation energy of the energy level adjustment layer 101a, and a fifth difference ΔEa5 exists between the average activation energy of the energy level adjustment layer 101a and the average activation energy of the host material of the light-emitting layer 104a. The absolute value of the fourth difference ΔEa4 and the absolute value of the fifth difference ΔEa5 are each greater than 0 eV.

In the related art, the highest occupied molecular orbital (HOMO)/lowest occupied molecular orbital (LOMO) is generally used to measure the energy level matching of the light-emitting device 10a. HOMO/LOMO only considers the injection efficiency of holes or electrons. However, in the embodiments of the present disclosure, the average activation energy is used to measure the energy level matching of the light-emitting device 10a, which further consider the injection efficiency and migration efficiency of holes based on comprehensive consideration of temperature, electron injection efficiency and migration efficiency. Compared to the traditional HOMO/LOMO method, the lifetime of the light-emitting device 10a may be further extended, and the light-emitting efficiency of the light-emitting device 10a is improved.

In the embodiments, the energy level adjustment layer 101a may be an electron blocking layer, and its material may be a single aromatic amine structure containing a spirofluorene group, a single aromatic amine structure containing a spiro ring unit, etc. This design of the energy level adjustment layer 101a may achieve the purpose of energy level matching and block the electrons of the cathode, to further improve the light-emitting efficiency of the light-emitting device 10a.

In addition, the material of the hole transport layer 103a may be poly(p-phenylene propylene), poly(thiophene), poly(silane), triphenylmethane, triarylamine, hydrazone, pyrazoline, chewazole, carbazole, butadiene, etc.

In some embodiments, when the light-emitting layer 104a is a blue light-emitting layer, the absolute value of the fourth difference ΔEa4 between the average activation energy of the hole transport layer 103a and the average activation energy of the energy level adjustment layer 101a is greater than or equal to 0.1 eV and less than or equal to 0.15 eV, and the absolute value of the fifth difference ΔEa5 between the average activation energy of the energy level adjustment layer 101a and the average activation energy of the host material of the light-emitting layer 104a is greater than or equal to 0.05 eV and less than or equal to 0.1 eV. For example, the absolute value of the fourth difference ΔEa4 may be 0.12 eV, 0.14 eV, etc., and the absolute value of the fifth difference ΔEa5 may be 0.06 eV, 0.08 eV, etc. The above-mentioned design method of the ranges of the fourth difference ΔEa4 and the fifth difference ΔEa5 may effectively increase the lifetime of the blue light-emitting layer, reduce the difference in lifetime between the blue light-emitting layer and the red light-emitting layer and the green light-emitting layer, and reduce the occurrence probability of color shift. Further, when the difference between the average activation energy of the electron transport layer 100a and the average activation energy of the energy level matching layer 102a is less than 0.05 eV, and the difference between the average activation energy of the energy level matching layer 102a and the average activation energy of the light-emitting layer 104a is 0.1-0.15 eV, the energy levels of the activation energy on both sides of the holes and the electrons may be matched to improve the equilibrium state of the electrons and the holes, thereby improving the light-emitting efficiency and lifetime, and improving the stability of the light-emitting device 10a with temperature changes.

In an application scenario, the average activation energy of the energy level adjustment layer 101a has a difference of −0.1 eV to −0.2 eV (for example, −0.15 eV, −0.18 eV, etc.) compared to the average activation energy of the hole transport layer 103a, and the average activation energy of the blue light-emitting layer has a difference of −0.2 eV to −0.3 eV (for example, −0.25 eV, −0.28 eV, etc.) compared to the average activation energy of the hole transport layer 103a. The above-mentioned design method may make the blue light-emitting device have a higher lifespan and light-emitting efficiency.

In order to verify the actual effect of the above design, the following Comparative Example 2 and Experimental Example 2 are designed, in which the absolute value of the fourth difference ΔEa4 between the average activation energy of the hole transport layer 103a and the average activation energy of the energy level adjustment layer 101a in Experimental Example 2 is 0.1 eV, the absolute value of the fifth difference ΔEa5 between the average activation energy of the energy level adjustment layer 101a and the average activation energy of the host material of the light-emitting layer 104a is 0.05 eV. The difference between Comparative Example 2 and Experimental Example 2 is that the light-emitting device in Comparative Example 2 does not include the energy level adjustment layer 101a. The performance test results of the light-emitting devices corresponding to Comparative Example 2 and Experimental Example 2 are shown in Table 1 below.

TABLE 1
Comparison table of performance test of light-
emitting devices corresponding to Comparative
Example 2 and Experimental Example 2

| | | | | | | LT95@ |
|---|---|---|---|---|---|---|
| | | | Von@ | | BI. | 1200 nit |
| | CIEx | CIEy | 1 nits (V) | Vd (V) | (cd/A/CIEy) | (hrs) |
| Experimental | 0.140 | 0.042 | 3.02 | 3.87 | 161.9 | 180 |
| Example 2 | | | | | | |
| Comparative | 0.141 | 0.042 | 3.01 | 3.87 | 128.8 | 129 |
| Example 2 | | | | | | |

It can be seen from the Table 1 that the color coordinates CIEx and CIEy of the light emitted by the light-emitting devices corresponding to Experimental Example 2 and Comparative Example 2 are basically the same, and the Von@ 1 nits and Vd of the light-emitting devices are also basically the same. Von@ 1 nits refers to the voltage value at tiny brightness of 1 nits; Vd refers to the voltage value at operating brightness of 1200 nits. As for the lifetime (LT95@1200 nit), a continuous electric current test (DC) was conducted with the initial brightness of 1200 nits, and LT95@ 1200 nit refers to a period of time taken for which the luminance was reduced to 95% as compared with the luminance at the time of starting the test. The BI value of Experimental Example 2 is 20% greater than that of Comparative Example 2, and the duration of Experimental Example 2 at 1200 nits brightness is 28% greater than that of Comparative Example 2, where BI is cd/A/CIEy, Cd/A is the light-emitting efficiency, and CIEy is the coordinates of CIExy1931. Since the blue light-emitting efficiency cd/A is easily affected by the value of CIEy, the industry generally defines the blue efficiency with the BI value. It can be seen from the above performance test results that the solution adopted in the embodiments of the present disclosure may significantly improve the light-emitting efficiency and light-emitting lifetime of the blue light-emitting device.

In addition, referring to FIG. 8, which is a schematic view of color coordinates of Comparative Example 2 and Experimental Example 2 as a function of time. It can be clearly seen from FIG. 8 that compared to Comparative Example 2, the lifetime of the blue light-emitting device increases with the passage of time, and the change of the color coordinates of white light decreases with the passage of time.

In an application scenario, when the light-emitting layer 104a is a blue light-emitting layer, and the blue light-emitting layer includes a blue light-emitting host material BH and a blue light-emitting doped material BD, a sixth difference ΔEa6 exists between the average activation energy of the energy level adjustment layer 101a and the average activation energy of the blue light-emitting doped material BD, and the absolute value of the sixth difference is less than the absolute value of the fifth difference ΔEa5. The main role of the blue light-emitting host material BH is to transfer energy and prevent triplet energy from being overwhelmed, and the main role of the blue light-emitting doped material BD is to transmit light. When the blue light-emitting layer emits light, energy is transferred between the blue light-emitting host material BH and the blue light-emitting doped material BD. The above-mentioned design method of the average activation energy may make the holes transported by the energy level adjustment layer 101a reach the blue light-emitting doped material BD more easily, and the blue light-emitting host material BH may effectively transfer energy to the blue light-emitting doped material BD, reducing the probability of energy reflow and ensuring light-emitting efficiency.

In addition, in the embodiments, the blue light-emitting host material BH has a difference of −0.2 eV to −0.3 eV in average activation energy compared to the hole transport layer 103a; the blue light-emitting doped material BD has a difference of −0.2 eV to −0.3 eV in average activation energy compared to the hole transport layer 103a. The blue light-emitting host material BH may be a carbazole group derivative, an aryl silicon derivative, an aromatic derivative, a metal complex derivative, etc., and the blue light-emitting doped material BD may be a fluorescent doped material (for example, porphyrin-based compounds, coumarin-based dyes, quinacridone-based compounds, aromatic amine-based compounds, etc.) or a phosphorescent dopant material (for example, complexes containing metal iridium, etc.).

Furthermore, when the absolute value of the fifth difference ΔEa5 between the average activation energy of the energy level adjustment layer 101a and the average activation energy of the blue light-emitting host material BH is greater than or equal to 0.1 eV and less than or equal to 0.15 eV, the absolute value of the sixth difference ΔEa6 between the average activation energy of the energy level adjustment layer 101a and the average activation energy of the light-emitting dopant material BD is less than 0.05 eV. For example, the absolute value of the sixth difference ΔEa6 may be 0.04 eV, 0.03 eV, etc. The design of the sixth difference ΔEa6 and the fifth difference ΔEa5 may effectively improve the light-emitting efficiency of the blue light-emitting layer; for example, the design of the fifth difference ΔEa5 is beneficial to accumulate a certain number of holes and electrons, which then combine to form excitons to enhance light-emitting efficiency. The design of the sixth difference ΔEa6 is conducive to the injection of holes from the energy level adjustment layer 101a into the blue light-emitting doped material BD.

In other embodiments, when the light-emitting layer 104a is a green light-emitting layer, the absolute value of the fourth difference ΔEa4 between the average activation energy of the hole transport layer 103a and the average activation energy of the energy level adjustment layer 101a is greater than or equal to 0.05 eV and less than or equal to 0.1 eV, and the absolute value of the fifth difference ΔEa5 between the average activation energy of the energy level adjustment layer 101a and the average activation energy of the green light-emitting host material of the light-emitting layer 104a is greater than or equal to 0.1 eV and less than or equal to 0.15 eV. For example, the absolute value of the fourth difference ΔEa4 may be 0.06 eV, 0.08 eV, etc., and the absolute value of the fifth difference ΔEa5 may be 0.14 eV, 0.13 eV, etc. The above-mentioned design method of the ranges of the fourth difference ΔEa4 and the fifth difference ΔEa5 may effectively improve the lifetime and light-emitting efficiency of the green light-emitting device.

In an application scenario, the green light-emitting layer may also be formed of a green light-emitting host material GH and a green light-emitting doped material GD, and a sixth difference ΔEa6 exists between the average activation energy of the energy level adjustment layer 101a and the average activation energy of the green doped material GD. The absolute value of the sixth difference ΔEa6 is less than 0.05 eV. An absolute value difference of 0.08-0.12 eV exists between the average activation energy of the green light-emitting host material GH and the average activation energy of the green light-emitting doped material GD. For example, the green light-emitting host material GH has a difference of 0.15 eV to 0.2 eV in average activation energy compared to the hole transport layer 103a, the green light-emitting doped material GD has a difference of 0.05 eV to 0.15 eV in average activation energy compared to the hole transport layer 103a, and the energy level adjustment layer 101a has a difference of 0.05 eV to 0.1 eV (for example, 0.06, 0.08 eV, etc.) in average activation energy compared to the hole transport layer 103a.

In other embodiments, when the light-emitting layer 104a is a red light-emitting layer, the absolute value of the fourth difference ΔEa4 between the average activation energy of the hole transport layer 103a and the average activation energy of the energy level adjustment layer 101a is greater than or equal to 0.1 eV and less than or equal to 0.15 eV, and the absolute value of the fifth difference ΔEa5 between the average activation energy of the energy level adjustment layer 101a and the average activation energy of the red light-emitting host material of the light-emitting layer 104a is less than 0.05 eV. For example, the absolute value of the fourth difference ΔEa4 may be 0.12 eV, 0.14 eV, etc., and the absolute value of the fifth difference ΔFa5 may be 0.04 eV, 0.03 eV, etc. The above-mentioned design method of the ranges of the fourth difference ΔEa4 and the fifth difference ΔEa5 may effectively improve the lifetime and light-emitting efficiency of the red light-emitting device.

In an application scenario, the red light-emitting layer may also be formed of a red light-emitting host material RH and a red light-emitting doped material RD, and a sixth difference ΔEa6 exists between the average activation energy of the energy level adjustment layer 101a and the average activation energy of the red doped material RD. The absolute value of the sixth difference ΔEa6 is less than 0.05 eV. An absolute value difference of 0.08-0.12 eV exists between the average activation energy of the red light-emitting host material RH and the average activation energy of the red light-emitting doped material RD. For example, the red light-emitting host material RH has a difference of 0.20 eV to 0.25 eV in average activation energy compared to the hole transport layer 103a, the red light-emitting doped material RD has a difference of 0.10 eV to 0.15 eV in average activation energy compared to the hole transport layer 103a, and the energy level adjustment layer 101a has a difference of 0.10 eV to 0.15 eV (for example, 0.12, 0.14 eV, etc.) in average activation energy compared to the hole transport layer 103a.

In addition, when the energy level adjustment layer 101a is an electron blocking layer, the light-emitting device provided by the embodiments of the present disclosure may further include: a third energy level layer disposed between the electron blocking layer and the light-emitting layer 104a, and the average activation energy of the third energy level layer is between the average activation energy of the electron blocking layer and the average activation energy of the light-emitting layer 104a. This design method may reduce the lifetime loss caused by the impact at the interface between the electron blocking layer and the light-emitting layer 104a and improve the lifetime of the light-emitting device.

And/or, the light-emitting device may further include a fourth energy level layer disposed between the electron blocking layer and the hole transport layer 103a, and the average activation energy of the fourth energy level layer is between the average activation energy of the electron blocking layer and the average activation energy of the hole transport layer 103a. This design method may reduce the lifetime loss caused by the impact at the interface between the electron blocking layer and the hole transport layer 103a and improve the lifetime of the light-emitting device.

Referring to FIG. 9, FIG. 9 is a structural schematic view of a display panel according to an embodiment of the present disclosure. The display panel 20 provided in the embodiment of the present disclosure may include the light-emitting device mentioned in any of the above-mentioned embodiments. The display panel 20 may include an array substrate 200, a light-emitting layer device 202, an encapsulation layer 204, etc. that are stacked. The light-emitting device layer 202 may include the light-emitting device mentioned in any of the foregoing embodiments, and the light-emitting device may be a blue light-emitting device, a red light-emitting device, or a green light-emitting device.

In this embodiment, when the light-emitting device layer 202 contains blue light-emitting device, red light-emitting device and green light-emitting device, the hole transport layers of the blue light-emitting device, red light-emitting device and green light-emitting device may be formed of the same material. The material of the energy level adjustment layer may be chosen according to the designed activation energy requirements. This design method may reduce the difficulty of process preparation. Of course, in other embodiments, the hole transport layers of the blue light-emitting device, the red light-emitting device, and the green light-emitting device may also be formed of different materials, which is not limited in the present disclosure.

The above are only examples of the present disclosure, and do not limit the scope of the present disclosure. Any equivalent structure or equivalent process transformation made using the content of the specification and drawings of the present disclosure, or applied directly or indirectly in other related technical fields, are included in the scope of the present disclosure in the same way.

What is claimed is:

1. A light-emitting device, comprising:
an electron transport layer, an energy level matching layer, and a light-emitting layer that are stacked; wherein a first difference exists between an average activation energy of the electron transport layer and an average activation energy of the energy level matching layer; a second difference exists between the average activation energy of the energy level matching layer and an average activation energy of a host material of the light-emitting layer; an absolute value of the first difference is less than an absolute value of the second difference.

2. The light-emitting device according to claim 1, wherein,
the light-emitting layer comprises a blue light-emitting layer; the absolute value of the first difference is less than 0.05 eV, and the absolute value of the second difference is greater than or equal to 0.1 eV and less than or equal to 0.15 eV.

3. The light-emitting device according to claim 2, wherein,
the average activation energy of the energy level matching layer has a difference of −0.05 eV to 0 eV compared to the average activation energy of the electron transport layer; an average activation energy of the blue light-emitting layer has a difference of 0.05 eV to 0.15 eV compared to the average activation energy of the electron transport layer.

4. The light-emitting device according to claim 2, wherein,
the blue light-emitting layer comprises a blue light-emitting host material and a blue light-emitting doped material; a third difference exists between an average activation energy of the blue light-emitting doped material and the average activation energy of the energy level matching layer; an absolute value of the third difference is less than the absolute value of the second difference.

5. The light-emitting device according to claim 4, wherein,
the absolute value of the third difference is less than 0.05 eV.

6. The light-emitting device according to claim 1, wherein,
the light-emitting layer comprises a green light-emitting layer; the absolute value of the first difference is less than 0.05 eV, and the absolute value of the second difference is less than 0.05 eV.

7. The light-emitting device according to claim 6, wherein,
the green light-emitting layer comprises a green light-emitting host material and a green light-emitting doped material; an absolute value of a difference between an average activation energy of the green light-emitting host material and an average activation energy of the green light-emitting doped material is between 0.05 eV and 0.1 eV, and an absolute value of a difference between the average activation energy of the green light-emitting doped material and the average activation energy of the energy level matching layer is less than 0.1 eV.

8. The light-emitting device according to claim 1, wherein,
the light-emitting layer comprises a red light-emitting layer; the absolute value of the first difference is less than 0.05 eV, and the absolute value of the second difference is less than 0.05 eV.

9. The light-emitting device according to claim 8, wherein,
the red light-emitting layer comprises a red light-emitting host material and a red light-emitting doped material; an absolute value of a difference between an average activation energy of the red light-emitting host material and an average activation energy of the red light-emitting doped material is between 0.08 eV and 0.12 eV, and an absolute value of a difference between the average activation energy of the red light-emitting doped material and the average activation energy of the energy level matching layer is between 0.08 eV and 0.12 eV.

10. The light-emitting device according to claim 1, wherein,
the energy level matching layer comprises a hole blocking layer.

11. The light-emitting device according to claim 10, further comprising:
a first energy level layer, disposed between the hole blocking layer and the light-emitting layer; wherein an average activation energy of the first energy level layer is between an average activation energy of the hole blocking layer and the average activation energy of the host material of the light-emitting layer.

12. The light-emitting device according to claim 10, further comprising:
a second energy level layer, disposed between the hole blocking layer and the electron transport layer; wherein an average activation energy of the second energy level layer is between an average activation energy of the hole blocking layer and the average activation energy of the electron transport layer.

13. The light-emitting device according to claim 1, wherein,
a current change rate of the energy level matching layer after a cyclic voltammetry test is less than 1%.

14. The light-emitting device according to claim 1, wherein a side of the light-emitting layer facing away from the energy level matching layer is arranged with:
an energy level adjustment layer and a hole transport layer that are stacked; wherein the energy level adjustment layer is disposed between the hole transport layer and the light-emitting layer; a fourth difference exists between an average activation energy of the hole transport layer and an average activation energy of the energy level adjustment layer, and a fifth difference exists between the average activation energy of the energy level adjustment layer and the average activation energy of the host material of the light-emitting layer.

15. The light-emitting device according to claim 14, wherein,
the light-emitting layer is a blue light-emitting layer; an absolute value of the fourth difference is greater than or equal to an absolute value of the fifth difference; the absolute value of the fourth difference is greater than or equal to 0.1 eV and less than or equal to 0.15 eV, and the absolute value of the fifth difference is greater than or equal to 0.05 eV and less than or equal to 0.1 eV.

16. The light-emitting device according to claim 15, wherein,
the blue light-emitting layer comprises a blue light-emitting host material and a blue light-emitting doped material; a sixth difference exists between the average activation energy of the energy level adjustment layer and an average activation energy of the blue light-emitting doped material, and an absolute value of the sixth difference is less than the absolute value of the fifth difference; the absolute value of the sixth difference is less than 0.05 eV.

17. The light-emitting device according to claim 14, wherein,
the light-emitting layer comprises a green light-emitting layer; an absolute value of the fourth difference is greater than or equal to 0.05 eV and less than or equal to 0.1 eV, and an absolute value of the fifth difference is greater than or equal to 0.1 eV and less than or equal to 0.15 eV.

18. The light-emitting device according to claim 17, wherein,
The green light-emitting layer comprises a green light-emitting host material and a green light-emitting doped material; a sixth difference exists between the average activation energy of the energy level adjustment layer and an average activation energy of the green light-emitting doped material, and an absolute value of the sixth difference is less than 0.05 eV.

19. The light-emitting device according to claim 14, wherein,
the light-emitting layer comprises a red light-emitting layer; an absolute value of the fourth difference is greater than or equal to 0.1 eV and less than or equal to 0.15 eV, and an absolute value of the fifth difference is less than 0.05 eV;
the red light-emitting layer comprises a red light-emitting host material and a red light-emitting doped material; a sixth difference exists between the average activation energy of the energy level adjustment layer and an average activation energy of the red light-emitting doped material, and an absolute value of the sixth difference is less than 0.05 eV.

20. A display panel, comprising a light-emitting device;
wherein the light-emitting device comprises:
an electron transport layer, an energy level matching layer, and a light-emitting layer that are stacked; wherein a first difference exists between an average activation energy of the electron transport layer and an average activation energy of energy level matching layer; a second difference exists between the average activation energy of the energy level matching layer and an average activation energy of a host material of the light-emitting layer; an absolute value of the first difference is less than an absolute value of the second difference.
